(19) United States
(12) Patent Application Publication
(10) Pub. No.: US 2025/0007243 A1
(43) Pub. Date: Jan. 2, 2025

(54) MONITOR UNIT AND OPTICAL MODULE

(71) Applicant: Sumitomo Electric Industries, Ltd., Osaka-shi, Osaka (JP)

(72) Inventors: Yuna OKINA, Osaka-shi, Osaka (JP); Hiromi NAKANISHI, Osaka-shi, Osaka (JP)

(73) Assignee: Sumitomo Electric Industries, Ltd., Osaka-shi, Osaka (JP)

(21) Appl. No.: 18/708,611

(22) PCT Filed: Jul. 15, 2022
(86) PCT No.: PCT/JP2022/027836

§ 371 Date: May 9, 2024

(30) Foreign Application Priority Data
Nov. 10, 2021 (JP) 2021-183153

(51) Int. Cl. H01S 5/0683; H01S 5/02212; H01S 5/02253; H01S 5/02257; H01S 5/02325

(52) U.S. Cl. CPC H01S 5/0683; H01S 5/02212; H01S 5/02253; H01S 5/02257; H01S 5/02325

(57) ABSTRACT

A monitor unit includes a holder, an optical branch portion configured to cause laser light to branch into first laser light and second laser light, and a photodetecting portion configured to detect the second laser light, wherein the optical branch portion and the photodetecting portion are fixed to the holder such that the second laser light is incident upon the photodetecting portion.

### TECHNICAL FIELD

The present disclosure relates to a monitor unit and an optical module. This application claims priority based on Japanese Patent Application No. 2021-183153 filed on Nov. 10, 2021, and the entire contents of the Japanese patent application are incorporated herein by reference.

### BACKGROUND ART

Light sources are known which has semiconductor laser elements, such as laser diodes, and housings for accommodating the semiconductor laser elements. When using semiconductor laser elements, it is common to monitor a portion of the laser light to maintain the desired output state. As described above, when semiconductor laser elements are accommodated in a housing, it is considered that a portion of laser light output from the housing to the outside is separated by a beam splitter or the like and the separated laser light is detected by a photodetector (refer to PTL 1 and PTL 2).

### CITATION LIST

### Patent Literature

PTL 1: Japanese Unexamined Patent Application Publication No. 2008-204550
PTL 2: Japanese Unexamined Patent Application Publication No. 2009-43305

### SUMMARY OF THE INVENTION

According to an embodiment, a monitor unit includes, a holder, an optical branch portion configured to cause laser light to branch into first laser light and second laser light, and a photodetecting portion configured to detect the second laser light. The optical branch portion and the photodetecting portion are fixed to the holder such that the second laser light is incident upon the photodetecting portion.

### BRIEF DESCRIPTION OF THE DRAWINGS

FIG. 1 is a perspective view of an optical module according to a first embodiment.

FIG. 2 is a perspective view of the optical module as seen from the bottom shown in FIG. 1.

FIG. 3 is an exploded perspective view of the optical module shown in FIG. 1.

FIG. 4 is a cross-sectional view of the optical module shown in FIG. 1 taken along the line IV-IV.

FIG. 5 is a front view of the optical module shown in FIG. 1.

FIG. 6 is a rear view of the optical module shown in FIG. 1.

FIG. 7 is a top view of the optical module shown in FIG. 1.

FIG. 8 is a bottom view of the optical module shown in FIG. 1.

FIG. 9 is a right side view of the optical module shown in FIG. 1.

FIG. 10 is a left side view of the optical module shown in FIG. 1.

FIG. 11 is a bottom view of the monitor unit of the optical module shown in FIG. 1.

FIG. 12 is a perspective view showing an optical module according to the second embodiment.

FIG. 13 is an exploded perspective view of the optical module shown in FIG. 12.

FIG. 14 is a cross-sectional view of the optical module shown in FIG. 12, taken along the line XIV-XIV.

FIG. 15 is a perspective view showing an optical module according to the third embodiment.

FIG. 16 is an exploded perspective view of the optical module shown in FIG. 15.

FIG. 17 is a cross-sectional view of the optical module shown in FIG. 15, taken along the line XVII-XVII.

FIG. 18 is a perspective view showing an optical module according to the fourth embodiment.

FIG. 19 is a perspective view of the optical module as seen from the bottom shown in FIG. 18.

FIG. 20 is an exploded perspective view of the optical module shown in FIG. 18.

FIG. 21 is a cross-sectional view of the optical module shown in FIG. 18, taken along the line XXI-XXI.

FIG. 22 is a front view of the optical module shown in FIG. 18.

FIG. 23 is a rear view of the optical module shown in FIG. 18.

FIG. 24 is a top view of the optical module shown in FIG. 18.

FIG. 25 is a bottom view of the optical module shown in FIG. 18.

FIG. 26 is a right side view of the optical module shown in FIG. 18.

FIG. 27 is a left side view of the optical module shown in FIG. 18.

FIG. 28 is a perspective view showing the optical module according to the fifth embodiment.

FIG. 29 is an exploded perspective view of the optical module shown in FIG. 28.

### DETAILED DESCRIPTION

### Problems to be Solved by the Present Disclosure

When laser light output from semiconductor laser elements housed in a housing (for example, a CAN type housing) is monitored outside the housing as described in PTL 1 and PTL 2, optical axis adjustment of a beam splitter and a photodetector is required. Therefore, the laser light output from the semiconductor laser elements cannot be easily monitored.

An object of the present disclosure is to provide a monitor unit capable of easily monitoring laser light output from a housing accommodating semiconductor laser elements and an optical module including the monitor unit. [Effects of Present Disclosure]

According to the present disclosure, it is possible to provide a monitor unit capable of easily monitoring laser light output from a housing accommodating semiconductor laser elements, and an optical module including the same.

### DESCRIPTION OF EMBODIMENTS OF PRESENT DISCLOSURE

First, the contents of embodiments of the present disclosure will be listed and explained.

According to an aspect of the present invention, a monitor unit includes, a holder, an optical branch portion configured to cause laser light to branch into first laser light and second laser light, and a photodetecting portion configured to detect the second laser light. The optical branch portion and the photodetecting portion are fixed to the holder such that the second laser light is incident upon the photodetecting portion.

In the above configuration, the optical branch portion and the photodetecting portion are fixed to the holder in advance in a positioned state described above. Therefore, by attaching the monitor unit to the light source part shown below, laser light can be easily monitored.

The holder may include, a first open end portion and a second open end portion, a hollow side wall portion, and an end wall portion provided at the first open end portion. A base portion may be configured to hold the optical branch portion in an inclined state with respect to a direction of output of the laser light is formed at the end wall portion. On an optical path of the second laser light, the photodetecting portion may be attached to an outer surface of the side wall portion. An optical passage allowing the second laser light to pass toward a side of the photodetecting portion may be formed at the side wall portion.

In the above configuration, when the holder is attached to the light source part, the window portion side of the housing of the light source part can be accommodated in the inner side of the side wall portion. Since the base portion holding the optical branch portion is formed at the end wall portion, the laser light output from the window portion can be branched into the first laser light and the second laser light in the optical branch portion held in the base portion. Since an optical passage allowing the second laser light to pass toward a side of the photodetecting portion is formed at the side wall portion, the second laser light can be detected by the photodetecting portion attached to the side surface of the side wall portion.

A cutout portion may have a first surface orthogonal to the optical path of the second laser light is provided at the outer surface of the side wall portion. The photodetecting portion may be fixed to the first surface.

By attaching the photodetecting portion to the cutout portion, the photodetecting portion can be easily attached, and the production efficiency can be improved.

The side wall portion may have a quadrilateral external shape when seen from the direction of output of the laser light.

Since the side wall portion is flat, the optical module can be easily attached to another member, and the productivity is improved. The volume as the heat sink is increased, and the grounding area is also increased, so that the heat can be efficiently released to the outside.

The end wall portion may include, a first end wall portion and a second end wall portion. The first end wall portion and the second end wall portion may be separated from each other with an optical path of the second laser light being interposed therebetween. The first end wall portion may have a first inclined surface inclined with respect to a direction of output of the laser light. The second end wall portion may have a second inclined surface inclined with respect to the direction of output of the laser light. The first inclined surface and the second inclined surface may constitute the base portion.

The first end wall portion and the second end wall portion are separated from each other with the optical path of the second laser light being interposed therebetween, and thus the laser light and the second laser light can pass through between the first end wall portion and the second end wall portion. Since the first inclined surface and the second inclined surface are formed at the first end wall portion and the second end wall portion, it is possible to secure the arrangement region of the optical branch portion. By fixing the optical branch portion to the first inclined surface and the second inclined surface, the optical branch portion can be arranged in a state of being inclined with respect to the direction of output of the laser light.

The end wall portion may include the first regions facing each other with the optical path of the second laser light being interposed therebetween and second regions facing each other with the optical branch portion being interposed therebetween. A distance between the second regions may be larger than a distance between the first regions. The first inclined surface and the second inclined surface may be surfaces connecting the first regions and the second regions to each other.

With the above configuration, it is easy to fix the optical branch portion to the first inclined surface and the second inclined surface while securing the region for arranging the optical branch portion.

The photodetecting portion may detect laser light in a visible range. The monitor unit needs to monitor the laser light of the visible light from the light source part. Therefore, the configuration of the monitor unit is effective.

An optical module according to an embodiment may include the monitor unit and a light source part for attaching the monitor unit thereto. The light source part may include, a semiconductor laser element configured to output the laser light, and a housing configured to accommodate the semiconductor laser element and including a window portion allowing the laser light to pass therethrough. The second open end portion may be fixed to a major surface of a supporting plate of the housing. The side wall portion may accommodate on an inner side thereof the window portion.

Since the optical module includes the monitor unit, the laser light output from the housing can be easily monitored.

A lens may be provided at the window portion. With this configuration, the light source part can be easily downsized, and as a result, the optical module can be easily downsized.

A window member not having a lens function may be provided at the window portion. This configuration can be applied to an optical system using a divergent beam.

The housing may include, a lens component so as to cover the window portion. A window member not having a lens function is provided at the window portion. With this configuration, an arbitrary lens component can be attached, and a desired optical system can be realized.

The optical module according to an embodiment may further include, a plurality of the semiconductor laser elements, and a multiplexer configured to multiplex a plurality of laser light beams that are output from the plurality of the semiconductor laser elements. The plurality of the semiconductor laser elements and the multiplexer may be accommodated in the housing. In this case, for example, it is capable to output multiplexed light of laser light of different colors.

The plurality of laser light beams may include, a red laser light beam, a blue laser light beam, and a green laser light beam. In this case, the optical module functions as a three color light source.

The optical module may include, an optical fiber and a ferrule. With this configuration, the laser light can be optically coupled to the optical fiber, and the optical module can be miniaturized as a whole.

### Details of Embodiments of Present Disclosure

Specific examples of embodiments of the present disclosure will be described below with reference to the drawings. The present invention is not limited to these examples, but is defined by the scope of the claims, and is intended to include all modifications within the meaning and scope equivalent to the scope of the claims. In the description of the drawings, the same elements are denoted by the same reference numerals, and redundant description will be omitted.

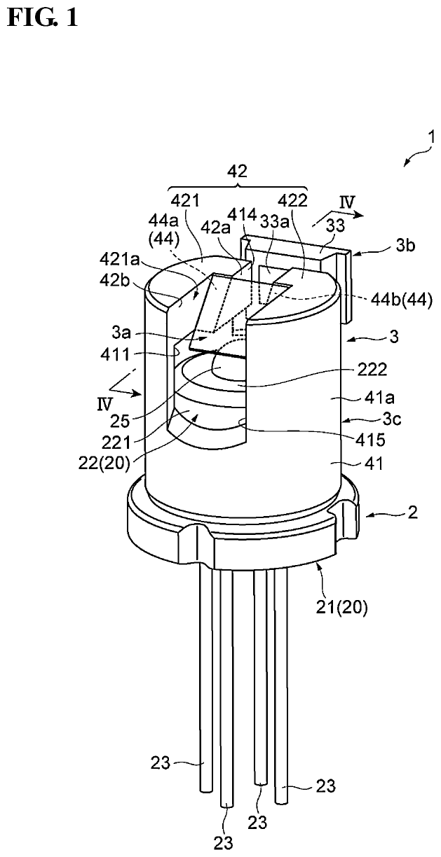

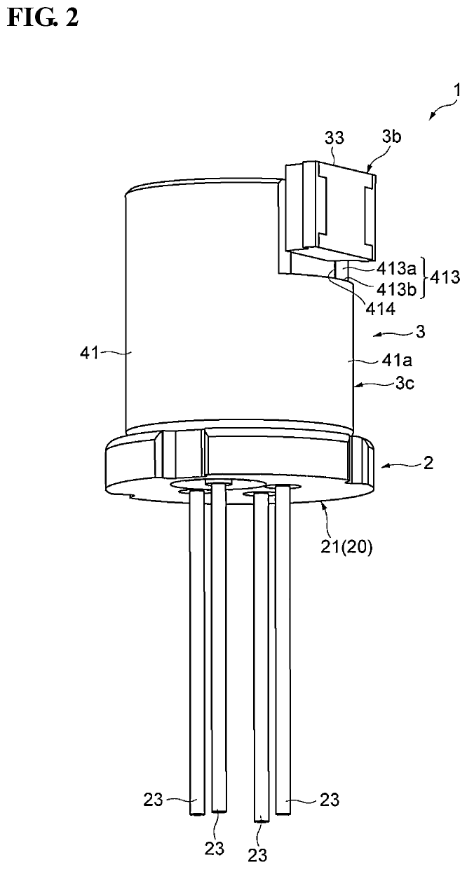

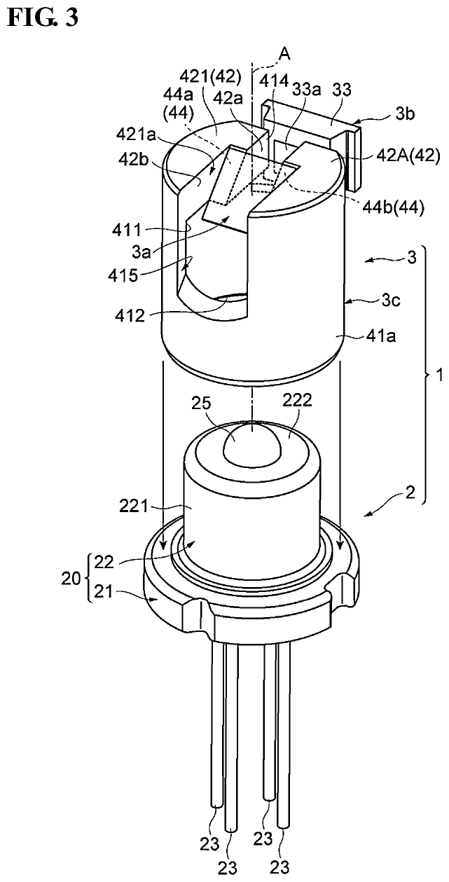

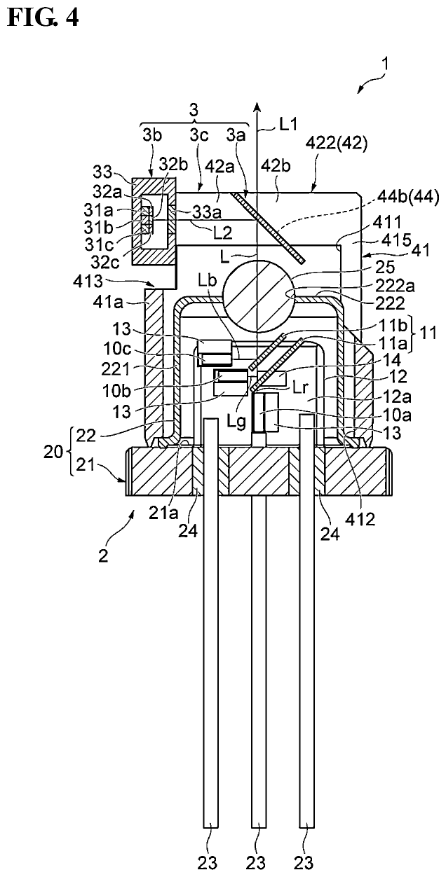

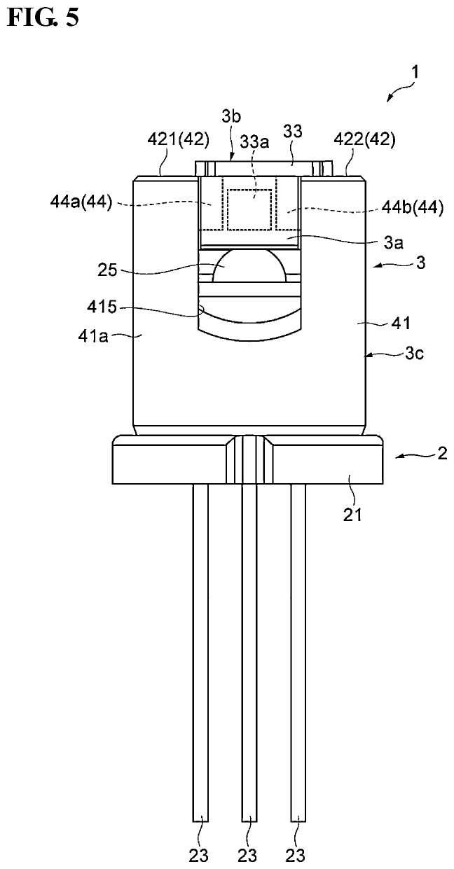

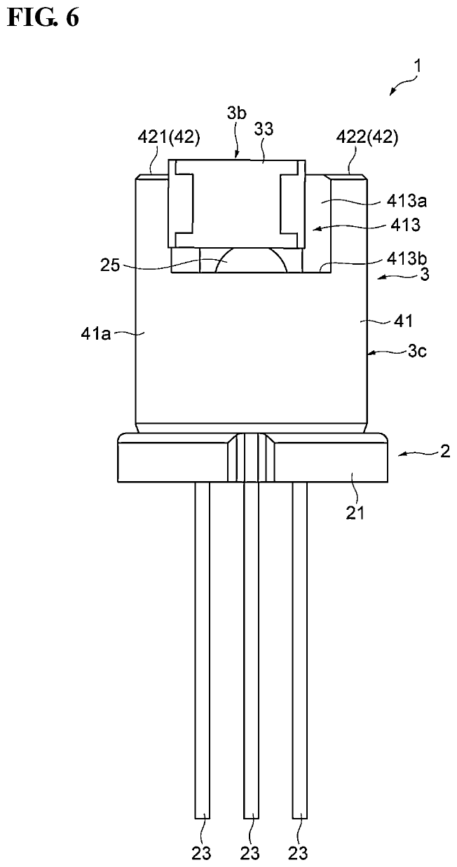

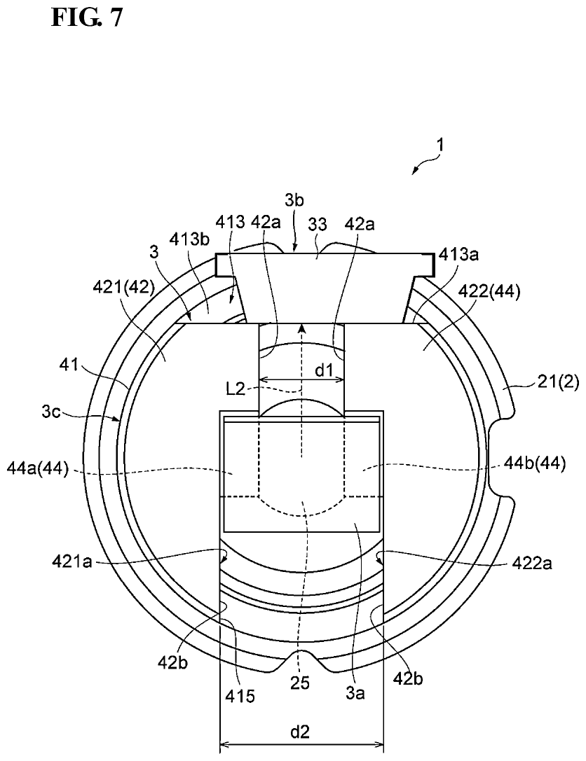

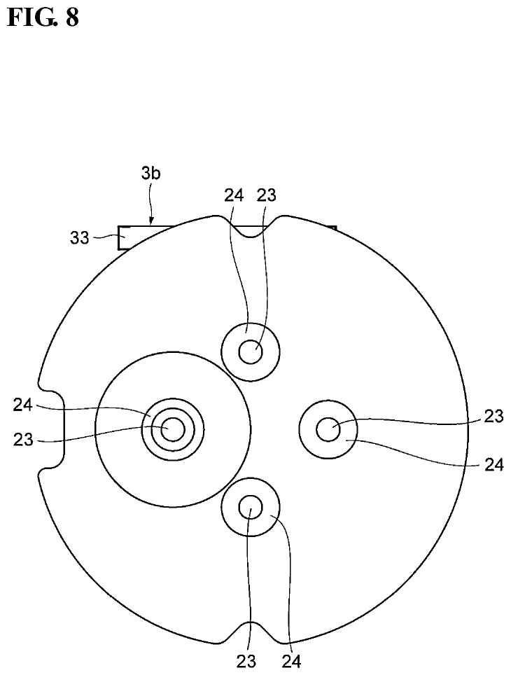

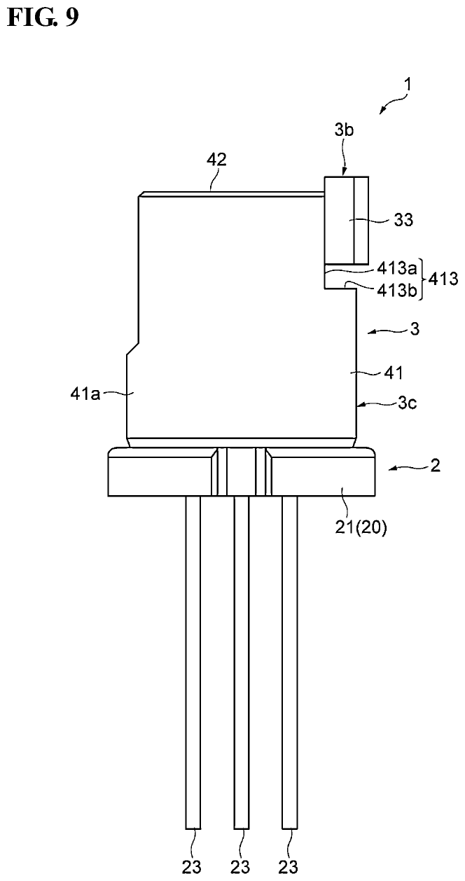

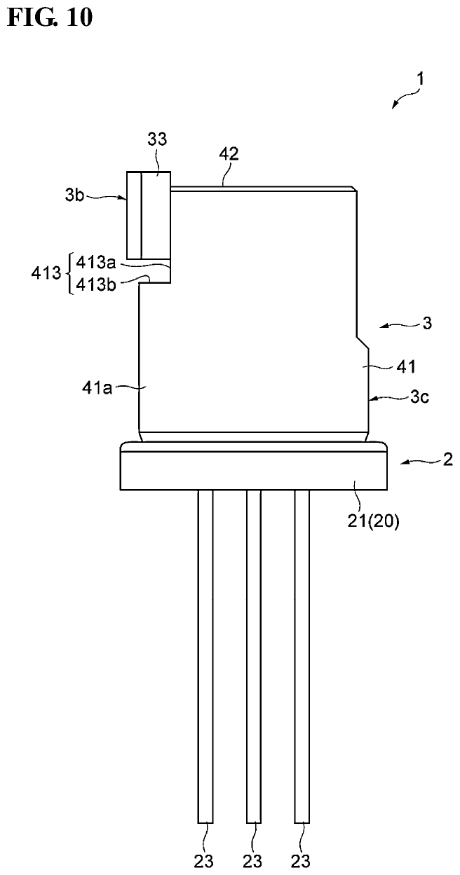

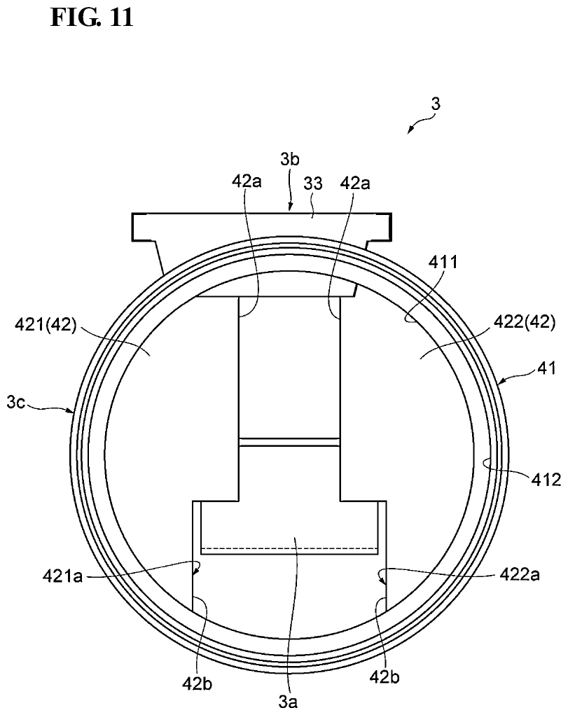

FIG. 1 is a perspective view of an optical module according to a first embodiment. FIG. 2 is a perspective view of the optical module shown in FIG. 1 as seen from the bottom shown in FIG. 1. FIG. 3 is an exploded perspective view of the optical module shown in FIG. 1. FIG. 4 is a cross-sectional view of the optical module shown in FIG. 1 taken along the line IV-IV. FIG. 5 is a front view of the optical module shown in FIG. 1. FIG. 6 is a rear view of the optical module shown in FIG. 1. FIG. 7 is a top view of the optical module shown in FIG. 1. FIG. 8 is a bottom view of the optical module shown in FIG. 1. FIG. 9 is a right side view of the optical module shown in FIG. 1, showing the optical module as viewed from the right side of FIG. 5. FIG. 10 is a left side view of the optical module shown in FIG. 1, showing the optical module as viewed from the left side of FIG. 5. FIG. 11 is a view of a monitor unit provided in the optical module as seen from the bottom shown in FIG. 1.

In the description of FIG. 1 to FIG. 11, directions such as “top”, “bottom”, “right”, and “left” are based on the state shown in FIG. 5 for convenience.

Optical module 1A includes light source part 2 for outputting a laser light L and monitor unit 3 for detecting a part of laser light L output from light source part 2.

As shown in FIG. 4, light source part 2 outputs laser light L. In one embodiment, light source part 2 is a light source module capable of outputting laser light L of a visible range. In the embodiment, light source part 2 is a light source module capable of outputting laser light L including at least one of a red laser light beam Lr, a green laser light beam Lg, and a blue laser light beam Lb. Light source part 2 is, for example, a CAN type light source module. Light source part 2 includes a first semiconductor laser element (first LD) 10a, a second semiconductor laser element (second LD) 10b, a third semiconductor laser element (third LD) 10c, multiplexer 11, and housing 20.

First LD 10a is a semiconductor laser element that outputs red laser light beam Lr. The oscillation wavelengths (or center wavelengths) of red laser light beam Lr are, for example, the wave length 620 nm to the wave length 650 nm. Second LD 10b is a semiconductor laser element that outputs green laser light beam Lg. The oscillation wavelengths (or center wavelengths) of green laser light beams Lg are, for example, the wavelengths 510 nm to the wavelengths 540 nm. Third LD 10c is a semiconductor laser element that outputs blue laser light beam Lb. The oscillation wavelengths (or center wavelengths) of blue laser light beams Lb are, for example, the wavelengths 435 nm to the wavelengths 465 nm. An example of first LD 10a, second LD 10b, and third LD 10c is a laser diode chip (LD chip).

First LD 10a, second LD 10b, and third LD 10c are mounted on supporting plate 12. First LD 10a, second LD 10b, and third LD 10c may be mounted on supporting plate 12 through base portion 13 (for example, a submount). Examples of the material of supporting plate 12 include metal and ceramic. As a material of base portion 13, a material having a thermal expansion coefficient close to that of the semiconductor material constituting first LD 10a, second LD 10b, and third LD 10c can be used, and for example, AlN, SiC, Si, or diamond can be used. When base portion 13 is used, the heights of red laser light beam Lr, green laser light beam Lg, and blue laser light beam Lb from major surface 12a on which first LD 10a, second LD 10b, and third LD 10c are mounted on supporting plate 12 can be adjusted by adjusting the height of base portion 13.

In the embodiment shown in FIG. 4, second LD 10b and third LD 10c are arranged laterally with respect to the optical axis of first LD 10a. Second LD 10b and third LD 10c are arranged on the same side with respect to the optical axis of first LD 10a. In other words, second LD 10b and third LD 10c are arranged on the same side with respect to the direction of output of red laser light beam Lr from first LD 10a, and are arranged such that the direction of output of green laser light beam Lg and blue laser light beam Lb from second LD 10b and third LD 10c crosses (in FIG. 4, substantially orthogonal to) the direction of output of red laser light beam Lr.

In the embodiment shown in FIG. 4, the optical axis of first LD 10a (the direction of output of red laser light beam Lr) is aligned with an optical axis A of light source part 2 (refer to FIG. 3). That is, the direction of output of laser light L from light source part 2 is aligned with the direction of output of red laser light beam Lr.

Multiplexer 11 is constituted to enable multiplex red laser light beam Lr, green laser light beam Lg, and blue laser light beam Lb. An example of multiplexer 11 will be described based on multiplexer 11 shown in FIG. 4. Multiplexer 11 includes filter 11a and filter 11b.

Filter 11a and filter 11b are, for example, wavelength selective filters. In one embodiment, filter 11a and filter 11b each include a multilayer filter (for example, a dielectric multilayer filter) formed on a transparent substrate. An example of a transparent substrate is a glass plate. The transparent substrate may also be a part of filter 11a and filter 11b.

Filter 11a transmits red laser light beam Lr and reflects green laser light beam Lg from second LD 10b toward filter 11b. Thus, red laser light beam Lr and green laser light beam Lg are combined. Filter 11b transmits the combined light of red laser light beam Lr and green laser light beam Lg (that is, red laser light beam Lr and green laser light beam Lg), and reflects blue laser light beam Lb from third LD 10c to the opposite side of filter 11a. Thus, laser light L, which is multiplexed light obtained by multiplexing red laser light beam Lr, green laser light beam Lg, and blue laser light beam Lb, is obtained.

The case where all of red laser light beam Lr, green laser light beam Lg, and blue laser light beam Lb are output has been described. However, when any one of red laser light beam Lr, green laser light beam Lg, and blue laser light beam Lb is not output, laser light L is light obtained by multiplexing laser light of the output color.

Filter 11a and filter 11b are mounted on supporting plate 12 in a arranged state so as to generate combined light of red laser light beam Lr, green laser light beam Lg, and blue laser light beam Lb. At least one of filter 11a and filter 11b may be mounted on supporting plate 12 through base portion 14.

Housing 20 accommodates first LD 10a, second LD 10b, and third LD 10c. As shown in FIG. 3 and FIG. 4, housing 20 includes supporting plate 21 and cover 22. In the embodiment, housing 20 is a CAN type housing.

As shown in FIG. 4, supporting plate 21 is a member to which supporting plate 12 on which first LD 10a, second LD 10b, third LD 10c, and multiplexer 11 are mounted is fixed. Supporting plate 12 is fixed to supporting plate 21 such that major surface 12a of supporting plate 12 and major surface 21a of supporting plate 21 are orthogonal to each other. Thus, laser light L is output in the normal direction of major surface 21a of supporting plate 21. Supporting plate 21 is, for example, a disc-shaped member. An example of supporting plate 21 is a stem. Examples of the material of supporting plate 21 include metal and ceramic.

A plurality of electrically conductive members 23 are passed through supporting plate 21 in the thickness direction. In the embodiment, four electrically conductive members 23 are passed through supporting plate 21. Each electrically conductive member 23 is a rod-shaped member extending in one direction, and is, for example, a lead pin. Each electrically conductive member 23 protrudes toward major surface 21a of supporting plate 21. The plurality of electrically conductive members 23 are used for power supply to first LD 10a, second LD 10b, and third LD 10c, a GND line, and the like. Electrically insulating member 24 is arranged around a portion of each electrically conductive member 23 located inside supporting plate 21 in order to prevent a short circuit between electrically conductive member 23 and supporting plate 21.

As shown in FIG. 3 and FIG. 4, cover 22 includes hollow side wall portion 221 having both open end portions, and end wall portion 222 for covering one of the open end portions. A flange portion may be formed at an end portion of side wall portion 221, which is adjacent to supporting plate 21.

Cover 22 may be a cap (CAN cap) in CAN type housing 20. Cover 22 is configured such that an open end portion of cover 22, which is not covered by end wall portion 222, is fixed to supporting plate 21. Thus, cover 22 and supporting plate 21 form an accommodation space for accommodating, for example, first LD 10a, second LD 10b, and third LD 10c. End wall portion 222 is, for example, hermetically sealed to supporting plate 21.

As shown in FIG. 4, end wall portion 222 is provided with an opening (window portion) 222a through which laser light L pass therethrough. Laser light L is output to the outside of housing 20 through opening 222a. In the embodiment, lens 25 is fitted into opening 222a. In the embodiment, lens 25 is a lens for converting laser light L into a convergent light, for example, a spherical lens.

### [Monitor Unit]

Monitor unit 3 is a unit for detecting a part of laser light L output from opening 222a. Monitor unit 3 includes optical branch portion 3a, photodetecting portion 3b, and holder 3c.

Optical branch portion 3a is arranged to be inclined with respect to the direction of output of laser light L from opening 222a (the direction of optical axis A of light source part 2). In the embodiment, except noted, the inclination angle of optical branch portion 3a relative to the direction of output of laser light L is 45 degrees. Optical branch portion 3a divides laser light L into a first laser light L1 and a second laser light L2.

First laser light L1 is a part of laser light L that travels along the direction of output of laser light L, and is an output light from optical module 1.

Second laser light L2 is a portion of laser light L that travels in a direction different from the direction of output of laser light L. In other words, second laser light L2 is light obtained by reflecting a portion of laser light L by optical branch portion 3a. Second laser light L2 is light (monitor light) for inspecting whether red laser light beam Lr, green laser light beam Lg, and blue laser light beam Lb are outputted from first LD 10a, second LD 10b, and third LD 10c in a desired output state.

As described above, first laser light L1 is the light outputted from optical module 1, and second laser light L2 is the light for inspection. Therefore, the light amount of first laser light L1 is larger than that of second laser light L2. An example of the reflectance of laser light L in optical branch portion 3a is 5% to 15%.

An example of optical branch portion 3a is a glass plate. In this case, second laser light L2 is obtained by Fresnel reflection at the surfaces of the glass plates.

Photodetecting portion 3b is arranged on the optical path of second laser light L2. Photodetecting portion 3b includes at least one of a parallel arranged first photodetector 31a, a parallel light source second photodetector 31b, and a parallel light source third photodetector 31c. Examples of first photodetector 31a, second photodetector 31b, and third photodetector 31c are photodiodes. First filter 32a, second filter 32b, and third filter 32c are arranged on the incident surface side of second laser light L2 in first photodetector 31a, second photodetector 31b, and third photodetector 31c. First filter 32a, second filter 32b, and third filter 32c are filters that selectively pass red laser light beam Lr, green laser light beam Lg, and blue laser light beam Lb. In such a configuration, first photodetector 31a detects red laser light beam Lr of second laser light L2, second photodetector 31b detects green laser light beam Lg of second laser light L2, and third photodetector 31c detects blue laser light beam Lb of second laser light L2.

First photodetector 31a, second photodetector 31b, and third photodetector 31c are electrically connected to a control unit (not shown). The control unit controls first LD 10a, second LD 10b, and third LD 10c so that red laser light beam Lr, green laser light beam Lg, and blue laser light beam Lb are in a desired state (a desired light amount or the like) in laser light L according to the detection results of first photodetector 31a, second photodetector 31b, and third photodetector 31c.

Photodetecting portion 3b includes housing 33 that houses first photodetector 31a, second photodetector 31b, and third photodetector 31c. Window portion 33a for passing second laser light L2 is formed at a wall of housing 33 on the incident side of second laser light L2. Window portion 33a may be constituted by fitting a transparent window member (for example, a glass plate) or the like into an opening formed in housing 33. An example of the shape of window portion 33a is a rectangle as shown in FIG. 5. The shape of window portion 33a may be a square or a circle.

The embodiment in which photodetecting portion 3b includes first photodetector 31a, second photodetector 31b, and third photodetector 31c has been described. However, the number of the photodetectors included in photodetecting portion 3b may be one. In this case, the incident surface of second laser light L2 in the photodetector is virtually divided into a first region, a second region, and a third region, and red laser light beam Lr, green laser light beam Lg, and blue laser light beam Lb are detected in the first region, the second region, and the third region. In such a form, first filter 32a, second filter 32b, and third filter 32c are arranged for the first region, the second region, and the third region.

Holder 3c is a member to which optical branch portion 3a and photodetecting portion 3b are fixed, and is attached to housing 20. Holder 3c functions as an adapter for arranging optical branch portion 3a and photodetecting portion 3b with respect to light source part 2. Holder 3c includes hollow side wall portion 41 (hollow body) and end wall portion 42.

As shown in FIG. 4 and FIG. 11, side wall portion 41 is a hollow member (hollow body) capable of accommodating a portion of housing 20 on opening 222a side in the inner side. Side wall portion 41 accommodates window portion 33a in the inner side. In the embodiment, side wall portion 41 is a cylinder. An example of the material of side wall portion 41 is metal (for example, stainless steel (SUS)). An example of side wall portion 41 is a cylindrical metal sleeve.

Side wall portion 41 includes first open end portion 411 and second open end portion 412. Second open end portion 412 is an end portion on the opposite side of first open end portion 411. Side wall portion 41 is fixed to housing 20 by joining second open end portion 412 to major surface 21a of supporting plate 21 included in housing 20. Side wall portion 41 may be fixed to supporting plate 21 by, for example, resistance welding or laser welding. Side wall portion 41 may be bonded to supporting plate 21 by an adhesive or may be bonded to supporting plate 21 by using solder.

A step portion (or cutout portion) 413 recessed toward the central axis of side wall portion 41 is formed at first open end portion 411 side of outer surface 41a of side wall portion 41. Step portion 413 functions as a portion (photodetecting portion mounting portion) on which photodetecting portion 3b is mounted. Step portion 413 includes first surface 413a intersecting the optical path of second laser light L2 and second surface 413b intersecting first surface 413a. In one embodiment, first surface 413a is orthogonal to the optical path of second laser light L2, and second surface 413b is orthogonal to first surface 413a. First surface 413a is a surface on which side photodetecting portion 3b is fixed, and in one embodiment, first surface 413a is a flat surface. Since side photodetecting portion 3b is arranged in step portion 413, the size of the protruding portion (protrusion) of photodetecting portion 3b with respect to side wall portion 41 can be reduced when viewed from the direction of output of laser light L.

Recessed portion 414 recessed from first open end portion 411 toward second open end portion 412 is formed in a part of side wall portion 41 (specifically, a portion where step portion 413 is formed). Recessed portion 414 functions as an optical passage for passing second laser light L2.

In side wall portion 41, recessed portion 415 recessed from first open end portion 411 toward second open end portion 412 may be formed in a region facing recessed portion 414. Hereinafter, except noted, recessed portion 415 will be described.

End wall portion 42 is provided in first open end portion 411. Base portion 44 is configured to hold optical branch portion 3a in an inclined state with respect to a direction of output of laser light L from opening 222a is formed at end wall portion 42. An example of end wall portion 42 will be described in detail.

End wall portion 42 includes first end wall portion 421 and a second end wall portion 422. As shown in FIG. 7, first end wall portion 421 and second end wall portion 422 are arranged to be separated from each other with the optical path (or recessed portion 414) of second laser light L2 interposed therebetween. In FIG. 7, second laser light L2 is shown by a dashed line to indicate the optical path of second laser light L2.

First end wall portion 421 has a first step portion 421a for securing an arrangement region of optical branch portion 3a toward second end wall portion 422. First step portion 421a is a portion of first end wall portion 421 that is recessed away from second end wall portion 422. First end wall portion 421 has a first step surface (first inclined surface) 44a inclined with respect to the direction of output of laser light L.

Second end wall portion 422 has a second step portion 422a for securing an arrangement region of optical branch portion 3a toward first end wall portion 421. Second step portion 422a is a portion recessed away from first end wall portion 421. Second end wall portion 422 has a second step surface (second inclined surface) 44b inclined with respect to the direction of output of laser light L. The inclination angle of second step surface 44b with respect to the direction of output of laser light L is the same as the inclination angle of first step surface 44a with respect to the direction of output of laser light L.

In the configuration of first end wall portion 421 and second end wall portion 422, the surfaces of first end wall portion 421 and second end wall portion 422 facing each other have a first region 42a and a second region 42b. First regions 42a face each other with the optical path of second laser light L2 interposed therebetween. Second regions 42b face each other with optical branch portion 3a interposed therebetween. First region 42a is a region closer to photodetecting portion 3b than second region 42b. As shown in FIG. 7, a distance d2 between second regions 42b of first end wall portion 421 and second end wall portion 422 is larger than a distance d1 between first regions 42a of first end wall portion 421 and second end wall portion 422. Distance d2 is a length where optical branch portion 3a can be arranged between first end wall portion 421 and second region 42b of second end wall portion 422.

A surface connecting first region 42a and second region 42b in first end wall portion 421 is inclined with respect to the direction of output of laser light L, and corresponds to first step surface 44a. A surface connecting first region 42a and second region 42b in second end wall portion 422 is inclined with respect to the direction of output of laser light L, and corresponds to second step surface 44b.

Optical branch portion 3a is fixed to first step surface 44a and second step surface 44b. That is, first step surface 44a and second step surface 44b function as base portion 44. Therefore, optical branch portion 3a is formed to be positioned on the optical path of laser light L. When optical branch portion 3a is in a plate shape such as a glass plate, the inclination angles of first step surface 44a and second step surface 44b substantially coincide with the inclination angle of optical branch portion 3a with respect to the direction of output of laser light L. Optical branch portion 3a may be fixed to first step surface 44a and second step surface 44b by using an adhesive or solder.

In monitor unit 3, optical branch portion 3a and photodetecting portion 3b are fixed to holder 3c. Photodetecting portion 3b detects second laser light L2 from optical branch portion 3a. Therefore, step portion 413 for fixing photodetecting portion 3b and base portion 44 (in detail, first step surface 44a and second step surface 44b) to which optical branch portion 3a is fixed are formed to be held by holder 3c in a state in which optical branch portion 3a and photodetecting portion 3b are aligned so that second laser light L2 is incident upon photodetecting portion 3b.

Holder 3c can be manufactured, for example, as follows. First, a first member including side wall portion 41 and the end wall portion completely covering first open end portion 411 of side wall portion 41 is manufactured. The first member can be manufactured by, for example, an NC lathe. Thereafter, the first member is processed to form, for example, step portion 413 for arranging photodetecting portion 3b, and first step portion 421a and second step portion 422a (including base portion 44) for arranging optical branch portion 3a. Thus, holder 3c is obtained. After holder 3c is manufactured, optical branch portion 3a is fixed to base portion 44 (in detail, first step surface 44a and second step surface 44b), and photodetecting portion 3b is fixed to step portion 413. Thus, monitor unit 3 is obtained.

Since side wall portion 41 of monitor unit 3 is hollow, window portion 33a and cover 22 can be accommodated in the inner side of side wall portion 221. Since optical branch portion 3a is held by base portion 44 formed at end wall portion 42, window portion 33a and cover 22 are accommodated in the inner side of side wall portion 41, and thus laser light L is incident upon optical branch portion 3a. Therefore, laser light L can be branched into first laser light L1 and second laser light L2 by optical branch portion 3a. Since recessed portion 414 for passing second laser light L2 is formed at side wall portion 41, photodetecting portion 3b can detect second laser light L2 even when photodetecting portion 3b is fixed to outer surface 41a of side wall portion 41.

In monitor unit 3, optical branch portion 3a and photodetecting portion 3b are fixed to side wall portion 41 in a state of being aligned with each other. Therefore, by covering cover 22 with side wall portion 41 and fixing to supporting plate 21, the positions of optical branch portion 3a and photodetecting portion 3b are automatically determined with respect to light source part 2. Therefore, when laser light L output from light source part 2 is monitored outside light source part 2, photodetecting portion 3b can be easily arranged, and as a result, laser light L can be easily monitored outside light source part 2.

The inclination angle of optical branch portion 3a is fixed, and optical branch portion 3a has a sufficient size to branch laser light L. Therefore, even when laser light L does not necessarily pass through the center of optical branch portion 3a, laser light L can be branched into first laser light L1 and second laser light L2, and second laser light L2 can be detected by photodetecting portion 3b.

In the form in which end wall portion 42 includes first end wall portion 421 and second end wall portion 422, since first end wall portion 421 and second end wall portion 422 are separated from each other with the optical path of second laser light L2 interposed therebetween, laser light L and second laser light L2 can pass between first end wall portion 421 and second end wall portion 422. Since first step portion 421a and second step portion 422a are formed at first end wall portion 421 and second end wall portion 422, the arrangement area of optical branch portion 3a can be secured. Since first step surface 44a and second step surface 44b are inclined surfaces, optical branch portion 3a can be arranged in a state of being inclined with respect to the direction of output of laser light L by fixing optical branch portion 3a to first step surface 44a and second step surface 44b.

In the form in which recessed portion 415 is formed at side wall portion 41, the region from the position of optical branch portion 3a to recessed portion 415 is opened in monitor unit 3 as shown in FIG. 1. Therefore, optical branch portion 3a can be easily fixed to base portion 44.

In optical module 1, light source part 2 does not include the photodetecting portion for monitoring the optical power states of first LD 10a, second LD 10b, and third LD 10c. Even in light source part 2, by covering monitor unit 3 on cover 22 and fixing to supporting plate 21, photodetecting portion 3b can be easily positioned with respect to light source part 2 as described above, and then a part of laser light L (second laser light L2) can be detected. As a result, first LD 10a, second LD 10b, and third LD 10c can be controlled to be in a desired output state.

In optical module 1, it is not necessary to arrange a photodetector for monitoring the optical output states of first LD 10a, second LD 10b, and third LD 10c in housing 20. Therefore, light source part 2 can be miniaturized, and as a result, optical module 1 can be miniaturized. For example, when optical module 1 is mounted on a wearable device such as a smart glasses, the configurations of optical module 1 and monitor unit 3 are effective.

In optical module 1 described in the embodiment, lens 25 is attached to cover 22. Therefore, for example, it is not necessary to arrange a lens or the like for condensing laser light or converting the laser light into parallel light in the accommodation space of first LD 10a, second LD 10b, and third LD 10c on the inner side of cover 22. Also in this respect, light source part 2 can be miniaturized.

Since it is not necessary to arrange a photodetector for monitoring the optical output states of first LD 10a, second LD 10b, and third LD 10c in housing 20, light source part 2 can be easily designed, and optical axis adjustment required when the photodetector is provided is not required. Therefore, light source part 2 can be easily manufactured, and as a result, optical module 1 can be easily manufactured.

Optical module 1 can be easily manufactured by attaching monitor unit 3 to a CAN type light source module (light source part 2 in the embodiment) that does not have a photodetector for monitoring the optical output states of first LD 10a, second LD 10b, and third LD 10c as described above, for example. Therefore, optical module 1 can be easily manufactured.

It is known that, in a laser diode (LD) that outputs laser light in a visible range, the optical outputs of the laser light output forward and backward are not in a proportional relationship. Therefore, when monitoring the laser light in the visible range output from the LD, it is necessary to divide the laser light output in the forward direction by the optical branch portion and detect the divided laser light by the photodetector. Therefore, when a photodetector for monitoring the output states of red laser light beam Lr, green laser light beam Lg, and blue laser light beam Lb output from first LD 10a, second LD 10b, and third LD 10c is arranged in light source part 2, the optical branch portion is also disposed in light source part 2 in addition to the photodetector.

In contrast, in the configuration of optical module 1 and monitor unit 3, as described above, photodetecting portion 30 for the monitor can be arranged outside light source part 2, and thus light source part 2 can be downsized. As a result, optical module 1 and monitor unit 3 are effective when light source part 2 includes an LD that outputs laser light in the visible range.

Light source part 2 does not have the photodetecting portion, while monitor unit 3 has photodetecting portion 3b.

Therefore, it is not necessary to pass electrically conductive member 23 for light detection through supporting plate 21 of housing 20. That is, the number of electrically conductive members 23 passing through supporting plate 21 can be reduced. Since monitor unit 3 includes photodetecting portion 3b, for example, a flexible printed circuit board (FPC) can be easily used. Since monitor unit 3 includes photodetecting portion 3b, photodetecting portion 3b can be easily replaced.

In a form in which light source part 2 includes first LD 10a, second LD 10b, third LD 10c, and multiplexer 11, laser light L may include red laser light beam Lr, green laser light beam Lg, and blue laser light beam Lb. Therefore, optical module 1 including light source part 2 can be used as a three color light source module.

### Second Embodiment

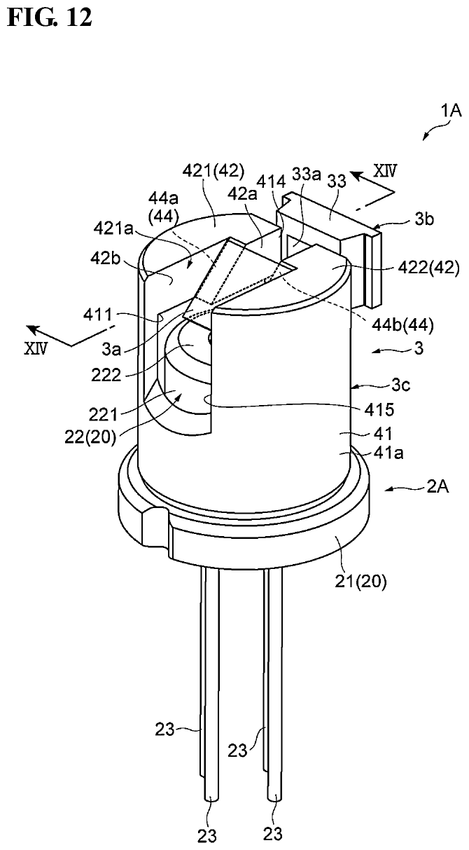

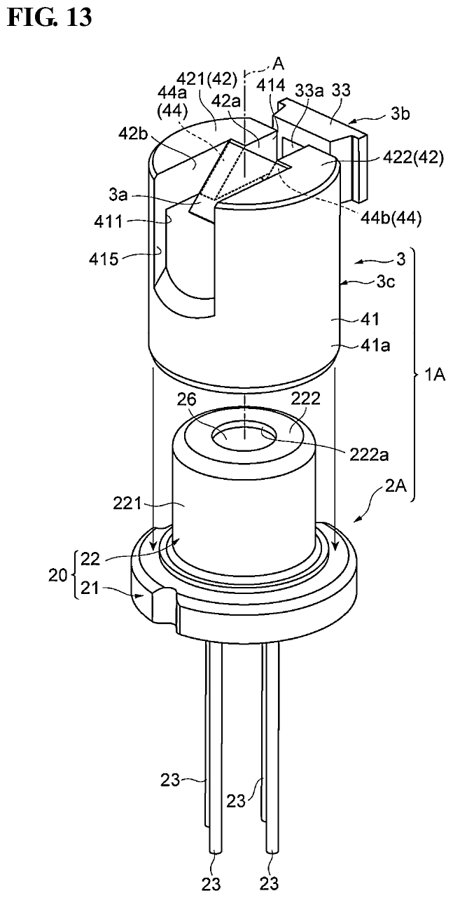

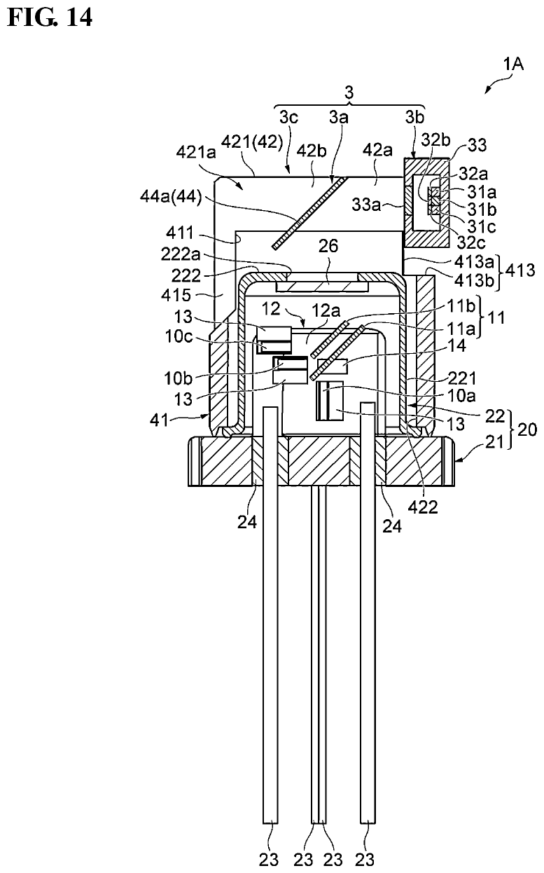

A second embodiment of the optical module will be described with reference to FIG. 12 to FIG. 14. FIG. 12 is a perspective view of another embodiment of an optical module. FIG. 13 is an exploded perspective view of the optical module shown in FIG. 12. FIG. 14 is a cross-sectional view of the optical module shown in FIG. 12 taken along the line XIV-XIV.

Optical module 1A shown in FIG. 12 to FIG. 14 has light source part 2A and monitor unit 3. Monitor unit 3 included in optical module 1A is the same as monitor unit 3 described in the first embodiment, and thus the description thereof will be omitted.

Light source part 2A is different from light source part 2 mainly in that opening 222a does not include a lens and window member 26 that does not have a lens function is attached to opening 222a. The configuration of optical module 1A other than these differences is the same as that of optical module 1, and therefore the above differences will be described, and the description of the other configurations will be omitted.

As shown in FIG. 14, in optical module 1A, window member 26 is fixed to the inner surface of end wall portion 222 so as to close opening 222a of end wall portion 222 of cover 22 from the inner side. An example of window member 26 is a glass plate. Window member 26 may be fitted into opening 222a. Window member 26 may be fixed to the outer surface of end wall portion 222 so as to cover opening 222a of cover 22 from the outside. In the form having window member 26, window member 26 may be a part of the window portion together with opening 222a.

Optical module 1A has the same configuration as optical module 1 except that optical module 1A includes light source part 2A instead of light source part 2. Further, light source part 2A has the same configuration as light source part 2 except that lens 25 is not provided and window member 26 is attached to opening 222a. Therefore, optical module 1A has the same operation and effect as optical module 1.

### Third Embodiment

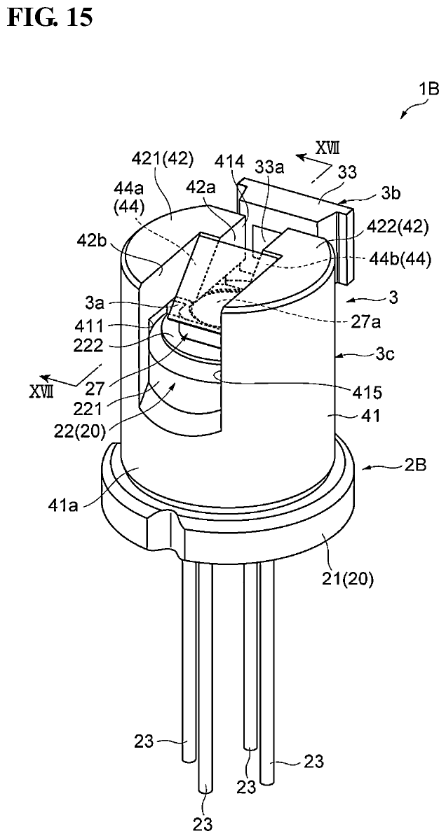

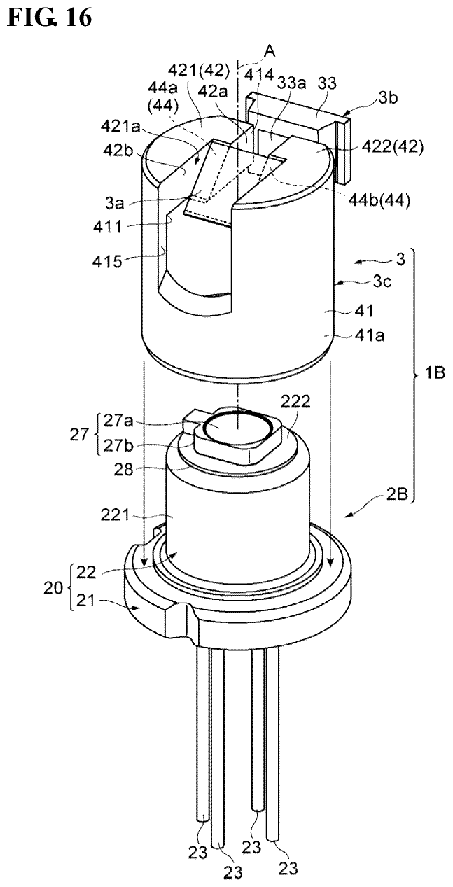

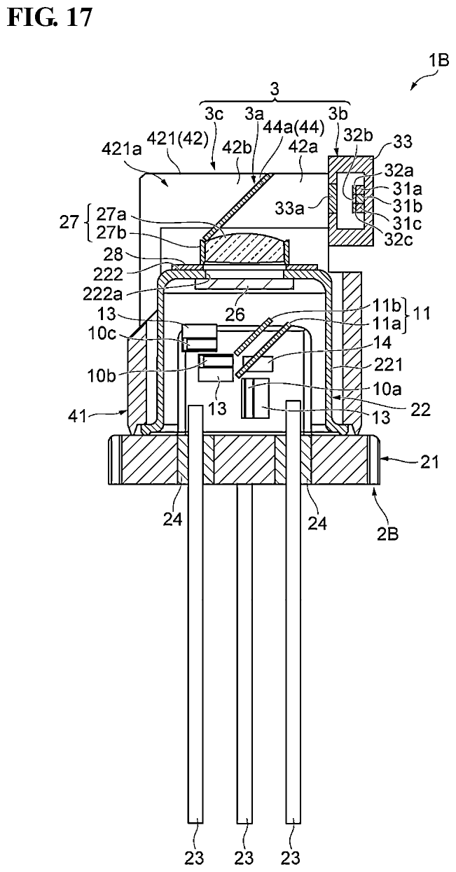

A third embodiment of the optical module will be described with reference to FIG. 15 to FIG. 17. FIG. 15 is a perspective view showing an optical module according to the third embodiment. FIG. 16 is an exploded perspective view of the optical module shown in FIG. 15. FIG. 17 is a cross-sectional view of the optical module shown in FIG. 15 taken along the line XVII-XVII.

Optical module 1B shown in FIG. 15 to FIG. 17 has light source part 2B and monitor unit 3. Monitor unit 3 included in optical module 1B is the same as monitor unit 3 described in the first embodiment, and thus the description thereof will be omitted.

Light source part 2 is different from light source part 2 mainly in that window member 26 having no lens function is attached to opening 222a and a lens component is attached to the outer surface of end wall portion 222 instead of lens 25. The configuration of optical module 1B other than these differences is the same as that of optical module 1, and therefore the above differences will be described, and the description of the other configurations will be omitted.

As shown in FIG. 17, in optical module 1B, as in the case of optical module 1A of the second embodiment, window member 26 is fixed to the inner surface of end wall portion 222 so as to close opening 222a of cover 22 from the inner side. An example of window member 26 is a glass plate. Window member 26 may be fitted into opening 222a.

Lens component 27 includes lens 27a. Lens component 27 may include holder 27b that holds lens 27a. In the embodiment shown in FIG. 17, lens 27a is fixed to the outer surface of end wall portion 222 in a state of being fitted in holder 27b. Lens 27a is provided so as to cover window member 26. Holder 27b may be fixed to end wall portion 222 through plate-shaped base portion 28. In this case, an opening corresponding to opening 222a is formed at base portion 28. An example of lens 27a is a collimating lens that collimates first laser light L1. Lens component 27 may include, for example, a plurality of lenses, and the collimating function may be realized by the plurality of lenses. Lens component 27 may have a function of converting first laser light L1 into light (for example, convergent light) other than collimated light.

Optical module 1B has the same configuration as optical module 1 except that optical module 1B includes light source part 2B instead of light source part 2. Furthermore, light source part 2B has the same configuration as light source part 2 except that window member 26 having no lens function is attached to opening 222a and that lens component 27 is attached to the outer surface of end wall portion 222 instead of lens 25. Therefore, optical module 1B has the same operation and effect as optical module 1A.

When lens component 27 has a collimating function, collimated laser light L is output from light source part 2B. Therefore, first laser light L1 as collimated light can be output from optical module 1B as well.

### Fourth Embodiment

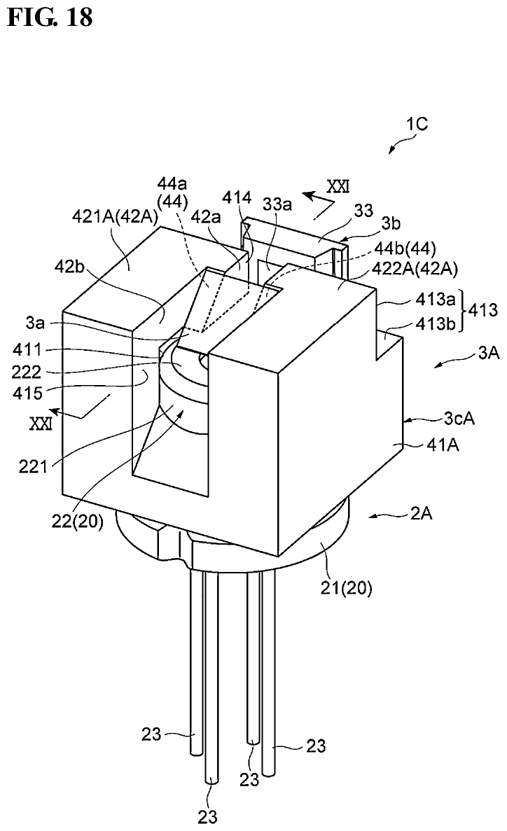

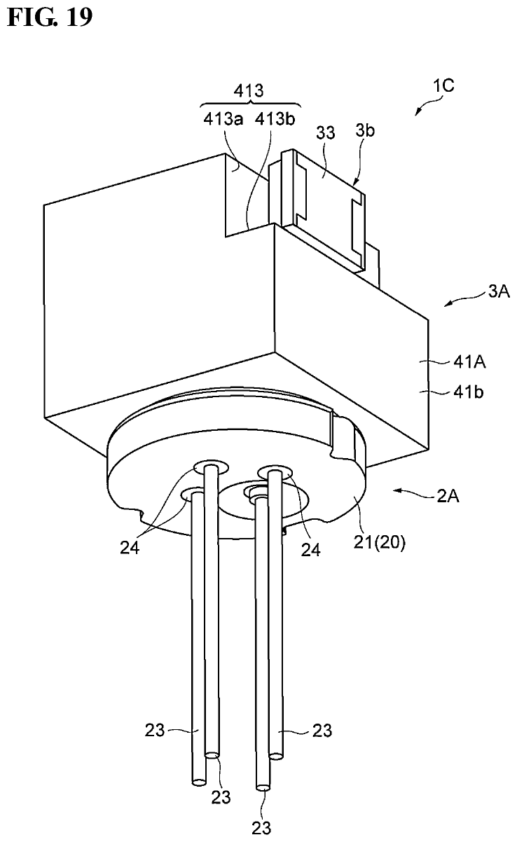

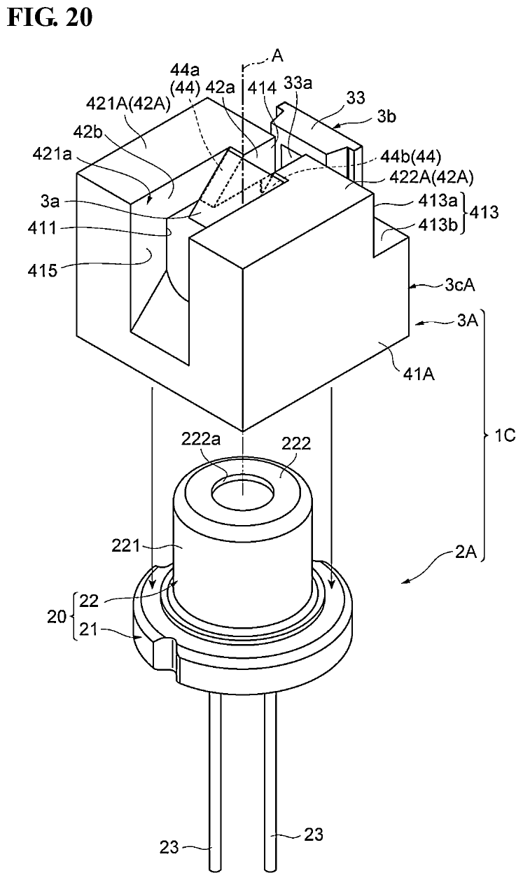

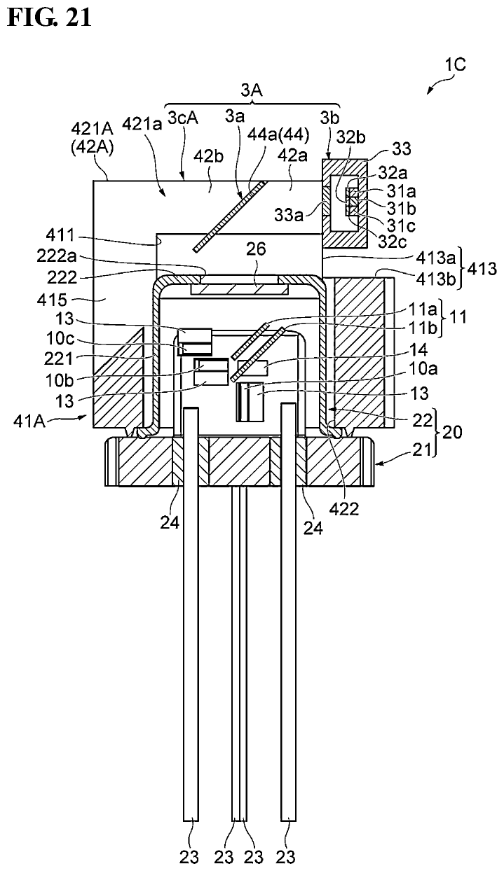

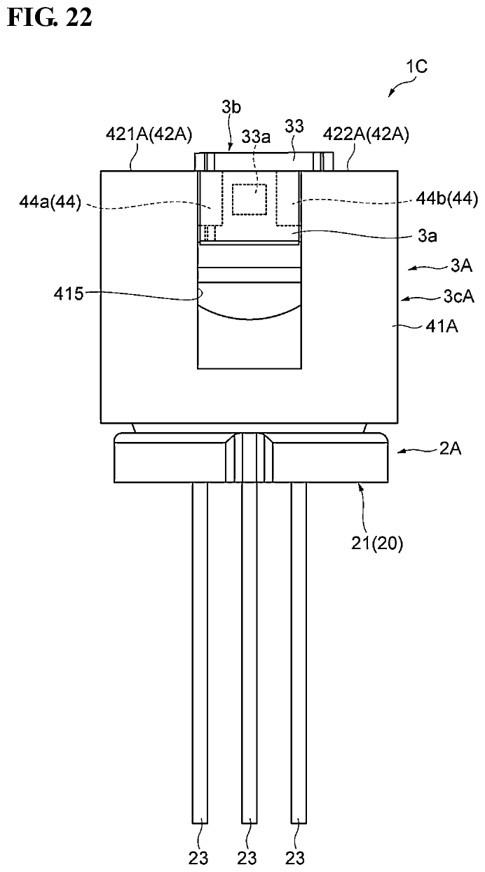

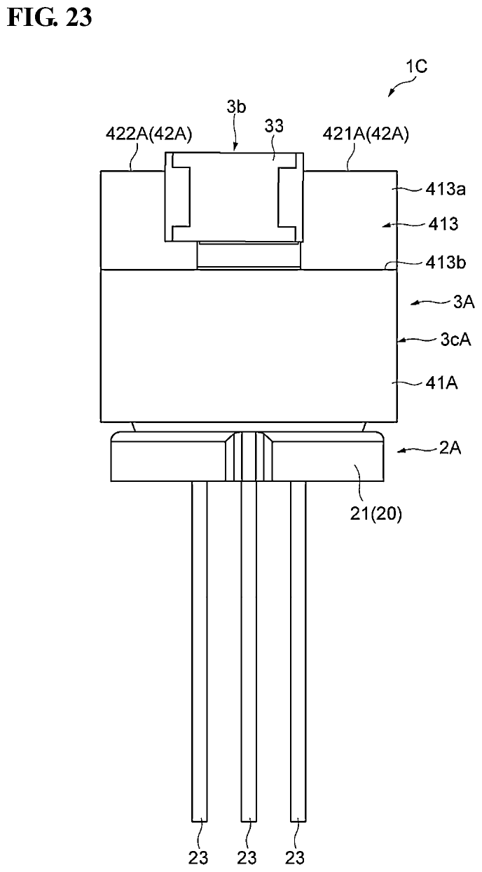

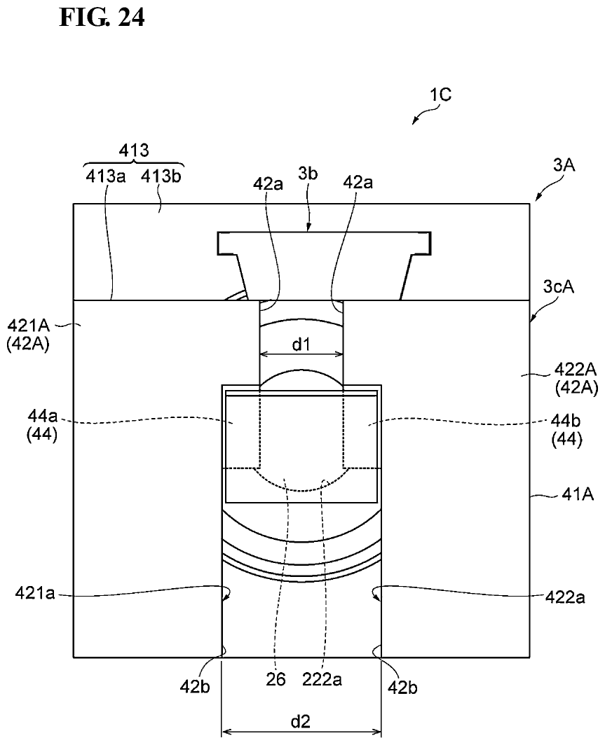

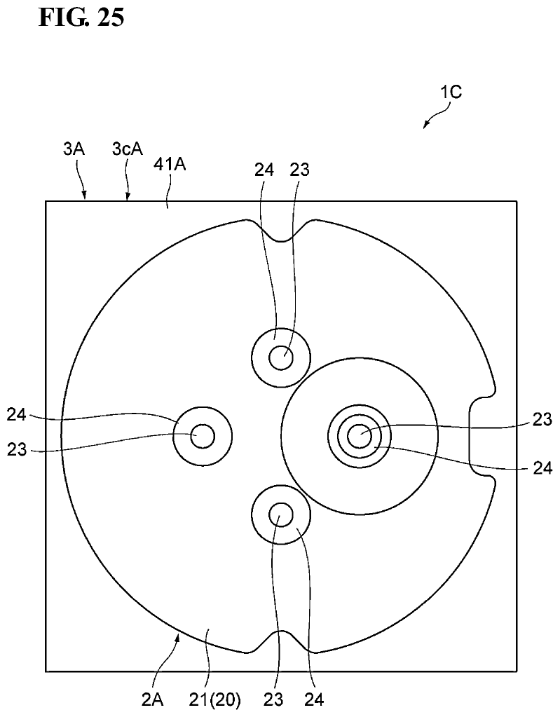

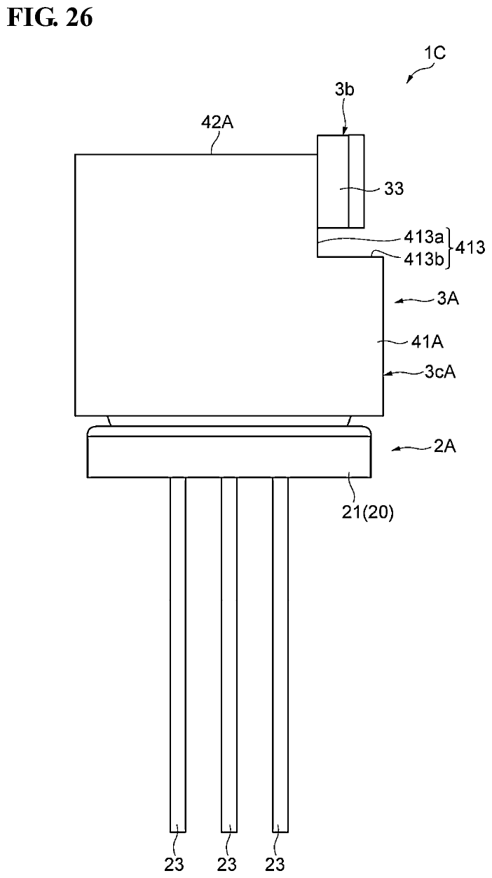

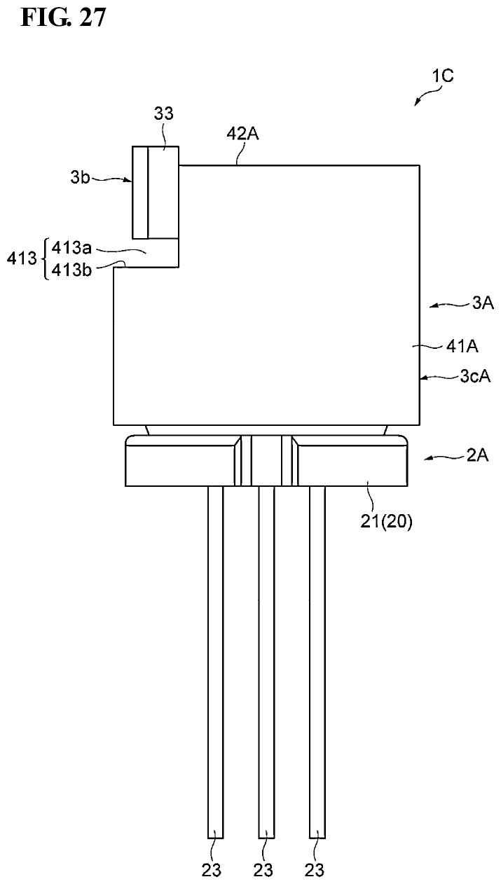

An optical module according to a fourth embodiment will be described with reference to FIG. 18 to FIG. 27. FIG. 18 is a perspective view showing an optical module according to the fourth embodiment. FIG. 19 is a perspective view of the optical module shown in FIG. 18 as seen from the bottom of FIG. 18. FIG. 20 is an exploded perspective view of the optical module shown in FIG. 18. FIG. 21 is a cross-sectional view of the optical module shown in FIG. 18 taken along the line XXI-XXI. FIG. 22 is a front view of the optical module shown in FIG. 18. FIG. 23 is a rear view of the optical module shown in FIG. 18. FIG. 24 is a top view of the optical module shown in FIG. 18. FIG. 25 is a bottom view of the optical module shown in FIG. 18. FIG. 26 is a right side view of the optical module shown in FIG. 18. FIG. 27 is a left side view of the optical module shown in FIG. 18.

In the description of FIG. 18 to FIG. 27, directions such as “top”, “bottom”, “right”, and “left” are based on the state shown in FIG. 22 for convenience.

Optical module 1C shown in FIG. 18 to FIG. 27 has light source part 2A and a monitor unit 3A. Light source part 2A included in optical module 1C is the same as light source part 2A described in the second embodiment, and thus the description thereof will be omitted.

Monitor unit 3A includes optical branch portion 3a, photodetecting portion 3b, and holder 3cA. The configurations of optical branch portion 3a and photodetecting portion 3b are the same as those of monitor unit 3 described in the first embodiment, and thus the description thereof will be omitted.

Holder 3cA is different from holder 3c described in the first embodiment mainly in that holder 3cA includes side wall portion 41A instead of side wall portion 41.

Side wall portion 41A in the fourth embodiment is different from side wall portion 41 in that the external shape when viewed from the direction of output of laser light L is a quadrilateral shape (for example, a square or a rectangle), for example, as shown in FIG. 18, FIG. 20, and FIG. 24. An example of side wall portion 41A is a square sleeve having a quadrangular external shape. Side wall portion 41A has first open end portion 411 and second open end portion 412, like side wall portion 41, and is hollow so as to accommodate opening 222a side (a portion of cover 22) of housing 20. In the embodiment, the inner shape of side wall portion 41A when viewed from the direction of output of laser light L is circular corresponding to the shape of cover 22, but may be rectangular as long as the portion of cover 22 can be accommodated.

In side wall portion 41A, second open end portion 412 is fixed to supporting plate 21 in the same manner as in the first embodiment.

Side wall portion 41A is formed at step portion 413 for attaching photodetecting portion 3b and recessed portion 414 for passing second laser light L2, similarly to side wall portion 41. Since the external shape of side wall portion 41A is a square shape as described above, step portion 413 is also a cutout portion constituted by cutting out a corner portion of one side surface 41b of side wall portion 41A and end wall portion 42A. Side wall portion 41A may include recessed portion 415 formed on a opposite side of recessed portion 414, as in side wall portion 41. Optical branch portion 3a can be easily attached to side wall portion 41A by recessed portion 415 is being formed.

First open end portion 411 of side wall portion 41A is provided with end wall portion 42A. End wall portion 42A has the same configuration as end wall portion 42 except that the shape of the boundary portion of end wall portion 42A with side wall portion 41A is different from that of the first embodiment according to the shape of side wall portion 41A. Therefore, base portion 44 for holding optical branch portion 3a is formed at end wall portion 42A.

In the fourth embodiment, end wall portion 42A may include a first end wall portion 421A and a second end wall portion 422A. The arrangement state of first end wall portion 421A and second end wall portion 422A is the same as the case of first end wall portion 421 and second end wall portion 422 in the first embodiment. The configurations of first end wall portion 421A and second end wall portion 422A are the same as those of first end wall portion 421 and second end wall portion 422 except that it differs from the case of the shape of a boundary portion between side wall portion 41A and first end wall portion 421A in accordance with the shape of side wall portion 41A and the shape of the boundary portion between side wall portion 41A and second end wall portion 422A of first end wall portion 421 in the first embodiment and second end wall portion 422. Therefore, the description of first end wall portion 421A and second end wall portion 422A will be omitted.

Optical module 1C is the same as optical module 1A according to the second embodiment except that monitor unit 3A is used instead of monitor unit 3. Monitor unit 3A has substantially the same configuration as monitor unit 3 except that the external shape of side wall portion 41A when viewed from the direction of output of laser light L is a quadrangular shape. Therefore, optical module 1C has the same operation and effect as optical module 1A (corresponding to the same operation and effect as optical module 1).

### Fifth Embodiment

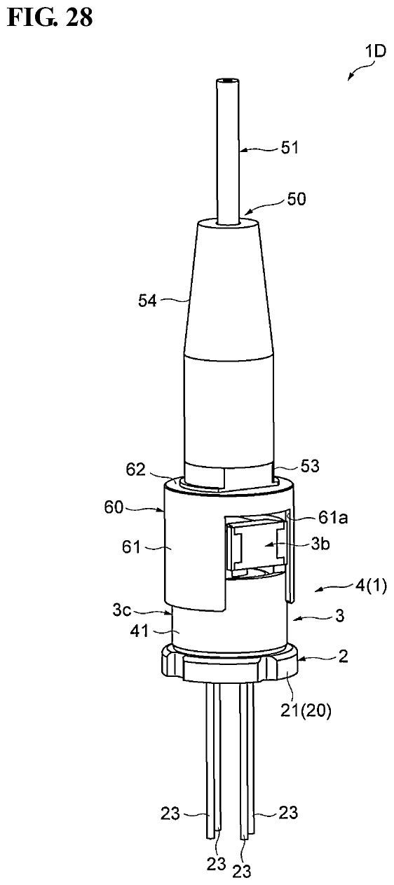

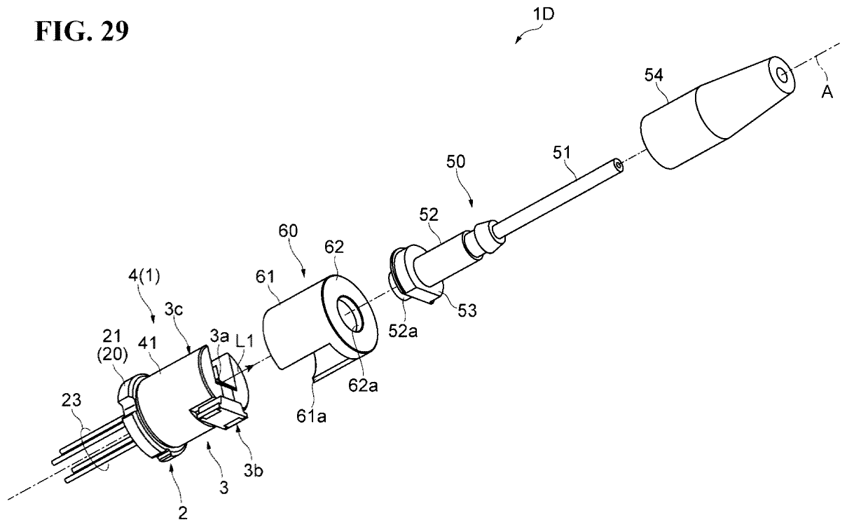

An optical module according to the fifth embodiment will be described with reference to FIG. 28 and FIG. 29. FIG. 28 is a perspective view showing an optical module according to a fifth embodiment. FIG. 29 is an exploded perspective view of the optical module shown in FIG. 28.

Optical module 1D shown in FIG. 28 and FIG. 29 is a pigtail-type optical module having optical outputting portion 4, an optical transmission medium 50, and a ferrule holder 60.

Optical outputting portion 4 is optical module 1 according to the first embodiment, and outputs first laser light L1. That is, optical outputting portion 4 includes light source part 2 and monitor unit 3, and monitor unit 3 is fixed to light source part 2. The configurations of light source part 2 and monitor unit 3 are the same as those in the first embodiment. Therefore, the description of light source part 2 and monitor unit 3 will be omitted.

As shown in FIG. 29, optical outputting portion 4, ferrule holder 60 and optical transmission medium 50 are arranged along the optical axis A (the direction of output of first laser light L1) of optical outputting portion 4.

Optical transmission medium 50 receives first laser light L1 output from optical outputting portion 4. Optical transmission medium 50 includes an optical fiber 51 and a ferrule 52.

Ferrule 52 is a hollow rod-shaped member. Ferrule 52 holds optical fiber 51 by inserting optical fiber 51 into ferrule 52. An example of the material of ferrule 52 is metal. A flange portion 53 (or a skirt portion) that defines the amount of insertion of ferrule 52 into ferrule holder 60 may be provided on the outer periphery of an end portion 52a of ferrule 52 on ferrule holder 60 side. Flange portion 53 may be integrated with ferrule 52. A protective cover 54 for protecting ferrule 52 and the vicinity of an insertion port (an end portion on the opposite side to ferrule holder 60) of optical fiber 51 in ferrule 52 may be attached to ferrule 52. Protective cover 54 is, for example, a rubber boot, and is covered on ferrule 52.

Ferrule holder 60 includes a side wall portion 61 and an end wall portion 62. Ferrule holder 60 is a member for attaching ferrule 52 to optical outputting portion 4 (optical module 1). Ferrule holder 60 can also function as a member for aligning the optical axis of optical fiber 51 with the optical axis of optical outputting portion 4.

Side wall portion 61 is hollow with both ends open. Side wall portion 61 is covered on side wall portion 41 of monitor unit 3 included in optical outputting portion 4. Side wall portion 61 can accommodate side wall portion 41 in the inner side and may have a shape that allows the optical axis of optical fiber 51 to be aligned with the optical axis of optical outputting portion 4 by covering side wall portion 41 with side wall portion 61.

For example, when side wall portion 41 is cylindrical as described in the first embodiment, side wall portion 61 may also be cylindrical. In this case, the inner diameter of side wall portion 61 substantially corresponds to the outer diameter of side wall portion 41. By covering side wall portion 61 over side wall portion 41, the inner surface of side wall portion 61 contacts the outer surface of side wall portion 41, thereby uniquely determining the position of side wall portion 61 relative to side wall portion 41. Therefore, by covering side wall portion 41 with side wall portion 61, the optical axis of optical fiber 51 and the optical axis of optical outputting portion 4 can be aligned.

A recessed portion 61a is formed at a portion of the side photodetecting portion 61 to be recessed from the open end portion on optical outputting portion 4 side toward the opposite side in order to avoid interference with side wall portion 3b.

End wall portion 62 is provided so as to close the open end portion of side wall portion 61 on optical transmission medium 50 side. End wall portion 62 is formed at an opening 62a through which first laser light L1 passes and into which end portion 52a of ferrule 52 is fitted. The inner diameter of opening 62a substantially corresponds to the outer diameter of end portion 52a. Opening 62a is formed at a position where optical axis A of optical outputting portion 4 and the optical axis of optical fiber 51 is aligned with each other in a state where ferrule holder 60 is covered on side wall portion 221 and end portion 52a is fitted into opening 62a.

In the above configuration, after end portion 52a of ferrule 52 is fitted into opening 62a, ferrule holder 60 is covered on side wall portion 41, so that optical axis A of optical outputting portion 4 can be aligned with the optical axis of optical fiber 51.

Optical module 1D includes optical outputting portion 4 which is optical module 1 of the first embodiment. Therefore, optical module 1D has the same operation and effect as optical module 1 and monitor unit 3.

While various embodiments have been described above, the present disclosure is not limited to the embodiments described above. For example, the number of semiconductor laser elements included in the light source part may be one or two. The number of semiconductor laser elements included in the light source part may be four or more. The semiconductor laser elements are not limited to laser diodes.

The various embodiments described above may be combined as appropriate without departing from the spirit of the present disclosure.

### REFERENCE SIGNS LIST

1 optical module
1A optical module
1B optical module
1C optical module
1D optical module
2 light source part
2A light source part
2B light source part
3 monitor unit
3A monitor unit
3a optical branch portion
3b photodetecting portion
3c holder
3cA holder
4 optical outputting portion
10a first LD (first semiconductor laser element)
10b second LD (second semiconductor laser element)
10c third LD (third semiconductor laser element)
11 multiplexer
12 supporting plate
13 base portion
12a major surface
11a filter
11b filter
14 base portion
20 housing
21 supporting plate
21a major surface
22 cover
221 side wall portion
222 end wall portion
222a opening (window portion)
23 electrically conductive member
24 electrically insulating member
25 lens
26 window member (window portion)
27 lens component
27a lens
27b holder
28 base portion
30 photodetecting portion
31a first photodetector
31b second photodetector
31c third photodetector
32a first filter
32b second filter
32c third filter
33 housing
33a window portion
41 side wall portion
41A side wall portion
411 first open end portion
412 second open end portion
413 step portion (cutout portion)
413a first surface
413b second surface
414 recessed portion
415 recessed portion
41a outer surface
41b side surface
42 end wall portion
42A end wall portion
421 first end wall portion
421A first end wall portion
421a first step portion
422 second end wall portion
422A second end wall portion
422a second step portion
42a first region
42b second region
44 base portion
44a first step surface (first inclined surface)
44b second step surface (second inclined surface)
50 optical transmission medium
51 optical fiber
52 ferrule
52a end portion
53 flange portion
54 protective cover
60 ferrule holder
61 side wall portion
61a recessed portion
62a opening
62 end wall portion
A optical axis
d2 distance
d1 distance
L laser light
L1 first laser light
L2 second laser light
Lr red laser light beam
Lg green laser light beam
Lb blue laser light beam

1. A monitor unit comprising:
a holder;
an optical branch portion configured to cause laser light to branch into first laser light and second laser light; and
a photodetecting portion configured to detect the second laser light,
wherein the optical branch portion and the photodetecting portion are fixed to the holder such that the second laser light is incident upon the photodetecting portion.

2. The monitor unit according to claim 1,
wherein the holder includes
a first open end portion and a second open end portion,
a hollow side wall portion, and
an end wall portion provided at the first open end portion,
wherein a base portion configured to hold the optical branch portion in an inclined state with respect to a direction of output of the laser light is formed at the end wall portion,
wherein, on an optical path of the second laser light, the photodetecting portion is attached to an outer surface of the side wall portion, and
wherein an optical passage allowing the second laser light to pass toward a side of the photodetecting portion is formed at the side wall portion.

3. The monitor unit according to claim 2,
wherein a cutout portion having a first surface orthogonal to the optical path of the second laser light is provided at the outer surface of the side wall portion, and
wherein the photodetecting portion is fixed to the first surface.

4. The monitor unit according to claim 2,
wherein, when seen from the direction of output of the laser light, an external shape of the side wall portion is a quadrilateral shape.

5. The monitor unit according to claim 1,
wherein the end wall portion includes a first end wall portion and a second end wall portion,
wherein the first end wall portion and the second end wall portion are separated from each other with an optical path of the second laser light being interposed therebetween,
wherein the first end wall portion has a first inclined surface inclined with respect to a direction of output of the laser light,
wherein the second end wall portion has a second inclined surface inclined with respect to the direction of output of the laser light, and
wherein the first inclined surface and the second inclined surface constitute the base portion.

6. The monitor unit according to claim 5,
wherein the end wall portion includes first regions facing each other with the optical path of the second laser light being interposed therebetween and second regions facing each other with the optical branch portion being interposed therebetween,
wherein a distance between the second regions is larger than a distance between the first regions, and
wherein the first inclined surface and the second inclined surface are surfaces connecting the first regions and the second regions to each other.

7. The monitor unit according to claim 1,
wherein the photodetecting portion detects laser light in a visible range.

8. An optical module comprising:
the monitor unit according to claim 1; and
a light source part for attaching the monitor unit thereto,
wherein the light source part includes
a semiconductor laser element configured to output the laser light, and
a housing configured to accommodate the semiconductor laser element and including a window portion allowing the laser light to pass therethrough,
wherein the second open end portion is fixed to a major surface of a supporting plate of the housing, and
wherein the side wall portion accommodates on an inner side thereof the window portion.

9. The optical module according to claim 8,
wherein a lens is provided at the window portion.

10. The optical module according to claim 8,
wherein a window member not having a lens function is provided at the window portion.

11. The optical module according to claim 8,
wherein the housing includes a lens component so as to cover the window portion, and
wherein a window member not having a lens function is provided at the window portion.

12. The optical module according to claim 8, further comprising:
a plurality of the semiconductor laser elements; and
a multiplexer configured to multiplex a plurality of laser light beams that are output from the plurality of the semiconductor laser elements,
wherein the plurality of the semiconductor laser elements and the multiplexer are accommodated in the housing.

13. The optical module according to claim 12,
wherein the plurality of laser light beams include a red laser light beam, a blue laser light beam, and a green laser light beam.

14. The optical module according to claim 8,
wherein the optical module includes an optical fiber and a ferrule.
